(19) United States
(12) Patent Application Publication
(10) Pub. No.: US 2018/0108314 A1
(43) Pub. Date: Apr. 19, 2018

(54) ARRAY SUBSTRATE, METHOD FOR DETECTING THE SAME AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Chengying CAO, Beijing (CN); Ruifang DU, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/724,810

(22) Filed: Oct. 4, 2017

(30) Foreign Application Priority Data
Oct. 13, 2016 (CN) 201610894959.3

(51) Int. Cl. G09G 3/36; H01L 27/12; H01L 23/58; G02F 1/1362; G02F 1/1333

(52) U.S. Cl. CPC G09G 3/3674; H01L 27/124; H01L 23/585; H01L 27/1248; G09G 2320/0693; G02F 1/136259; G02F 1/133345; G02F 2001/136254; G02F 1/136286

(57) ABSTRACT

An array substrate, a method for detecting the array substrate and a display device are provided. At least one test line is disposed on the array substrate and the at least one test line and multiple driving-signal traces overlap with each other. A position where one of the driving-signal traces and the test line overlap with each other is short-circuited to provide a driving signal on the driving-signal trace to an external detection device through a corresponding connection terminal electrically connected with one end of the test line, when a test on the driving signal on the driving-signal trace is performed.

### CROSS-REFERENCE TO RELATED APPLICATION

This application claims priority to Chinese Patent Application No. 201610894959.3 filed on Oct. 13, 2016, which is incorporated herein by reference in its entirety.

### TECHNICAL FIELD

The present disclosure relates to the field of display, and in particular to an array substrate, a method for detecting the array substrate and a display device including the array substrate.

### BACKGROUND

With a rapid development of display technologies, a liquid-crystal display technology called High Aperture Advanced Super Dimensional Switching (H-ADS) has drawn considerable attention due to characteristics thereof, such as a high aperture, a wide viewing angle, a high image quality, a fast response speed, and the like. A gate driving circuit is typically used to input a driving signal to a gate line in a H-ADS display panel when the H-ADS display panel displays, so that a thin film transistor connected to the gate line may be switched on to input a data signal and thereby realize a display function.

Generally, when a test is performed on the driving signal of the gate line in the H-ADS display panel, no test terminal in the H-ADS display panel is reserved for the test due to a process of manufacturing the H-ADS display panel. Hence, when testing the driving signal of the gate line, the gate line is generally separated from other film layers to expose the gate line, and then, the exposed gate line is tested. In a process of performing the test, the gate line may be damaged, such as be cut, causing that a thin film transistor (TFT) connected to the gate line is unable to receive the driving signal normally, or even the display panel cannot be illuminated and the display signal cannot be detected correctly.

### SUMMARY

Embodiments of the present disclosure provide an array substrate, a method for detecting the array substrate and a display device including the array substrate.

In a first aspect, an array substrate is provided and includes a display region including a plurality of gate lines; and a non-display region including at least one test line, a plurality of driving-signal traces, and a gate driving circuit including a plurality of driving-signal output terminals, wherein a first end of each of the plurality of driving-signal traces is electrically connected with one of the plurality of driving-signal output terminals, a second end of the driving-signal trace is electrically connected with one of the plurality of gate lines, and the at least one test line overlaps with and is insulated from at least one of the plurality of driving-signal traces.

Optionally, the array substrate further includes a repairing circuit electrically connected with a first end of the at least one test line.

Optionally, the non-display region further includes at least one connection terminal configured to be electrically connected with at least one detection terminal on a detection circuit, wherein the at least one connection terminal is electrically connected with a second end of the at least one test line.

Optionally, an angle other than zero degree exists between an extension direction of the at least one test line and an extension direction of each of the plurality of driving-signal traces.

Optionally, the array substrate further includes a source-drain electrode layer, wherein the source-drain electrode layer is located at one side of the array substrate having the plurality of driving-signal traces and is insulated from the plurality of driving-signal traces, and the at least one test line and the source-drain electrode layer are located at a same layer and are made of a same material.

Optionally, the gate driving circuit includes a first gate driving sub-circuit and a second gate driving sub-circuit located at both ends of each of the plurality gate lines, respectively, and each of the at least one test line includes a first test sub-line and a second test sub-line.

Optionally, the array substrate further includes a base substrate, wherein, the display region and the non-display regions are arranged on the base substrate, and an orthographic projection of the first test sub-line on the base substrate is located between an orthographic projection of the first gate driving sub-circuit on the base substrate and orthographic projections of the plurality of gate lines on the base substrate, and an orthographic projection of the second test sub-line on the base substrate is located between an orthographic projection of the second gate driving sub-circuit on the base substrate and orthographic projections of the plurality of gate lines on the base substrate.

Optionally, the array substrate further includes: a first insulation layer located between a layer at which the at least one test line is located and a layer at which the plurality of driving-signal traces are located.

Optionally, the array substrate further includes a second insulation layer located above the at least one test line and made of a material with a waterproof function.

Optionally, the gate driving circuit includes a plurality of shift registers cascaded to form a plurality of stages, each of the plurality of shift registers is configured to output a driving signal through a corresponding one of the plurality of driving-signal output terminals of the gate driving circuit.

In a second aspect, a display device including the above the array substrate is provided.

Optionally, the display device further includes a detection device including at least one detection terminal, wherein the non-display region further includes at least one connection terminal electrically connected with a second end of the at least one test line and each of the at least one connection terminal is configured to be electrically connected with one of the at least one detection terminal on the detection device.

Optionally, the detection circuit is a flexible circuit board or a printed circuit board.

Optionally, in case that the detection device is the printed circuit board, the display device further includes a flexible circuit board configured to electrically connect the at least one connection terminal with the at least one detection terminal.

In a third aspect, a method for detecting the above array substrate is provided and includes short-circuiting at least one of the plurality of driving-signal traces to be detected and the at least one test line; and electrically connecting a detection device with at least one connection terminal electrically connected to the at least one test line, and detecting a driving signal on the at least one test line.

Optionally, after short-circuiting at least one of the plurality of driving-signal traces to be detected and the at least one test line, the method further includes: electrically disconnecting the short-circuited at least one of the plurality of driving-signal traces from at least one of the plurality of driving-signal output terminals in the gate driving circuit; and inputting a corresponding driving signal to the disconnected at least one of the plurality of driving-signal traces through the at least one test line.

Optionally, the short-circuiting at least one of the plurality of driving-signal traces to be detected and the at least one test line includes: welding the at least one of the plurality of driving-signal traces to be detected and the at least one test line at a position where the at least one of the plurality of driving-signal traces to be detected and the at least one test line overlap with each other by a laser so as to short-circuit the at least one of the plurality of the driving-signal traces to be detected and the at least one test line.

Optionally, electrically disconnecting the short-circuited at least one of the plurality of driving-signal traces from at least one of the plurality of driving-signal output terminals in the gate driving circuit, includes: electrically disconnecting the short-circuited at least one of the plurality of driving-signal traces from at least one of the plurality of driving-signal output terminals of a plurality of shift registers cascaded to form a plurality of stages in the gate driving circuit, and each of the plurality of driving-signal output terminals corresponds to one of the plurality of shift registers.

### BRIEF DESCRIPTION OF THE DRAWINGS

FIG. 1 is a schematic top view of an array substrate provided by embodiments of the present disclosure;

FIG. 2 is a schematic top view of an array substrate provided by the embodiments of the present disclosure;

FIG. 3 is a schematic top view of an array substrate provided by the embodiments of the present disclosure;

FIG. 4A is a schematic sectional view of the array substrate shown in FIG. 1 taken along a line A-A′;

FIG. 4B is a schematic sectional view of the array substrate shown in FIG. 1 taken along a line B-B′;

FIG. 5A is a flow chart of a method for detecting an array substrate provided by the embodiments of the present disclosure;

FIG. 5B is a further flow chart of one step in the method shown in FIG. 5A; and

FIG. 6 is a structural schematic diagram of a gate driving circuit of the embodiments of the present disclosure.

### DETAILED DESCRIPTION

In order to make objectives, technical solutions and advantages of the present disclosure more clear, an array substrate, a method for detecting the array substrate and a display device provided by embodiments of the present disclosure will be described hereinafter in details in combination with accompanied drawings. It should be noted that same or similar reference numerals herein refer to the same or similar elements, or elements with same or similar functions.

A thickness, a size and a shape of each film layer and a thickness of a line in the accompanied drawings are only used to illustrate technical contents of the present disclosure, but do not reflect real scales of the elements in the array substrate.

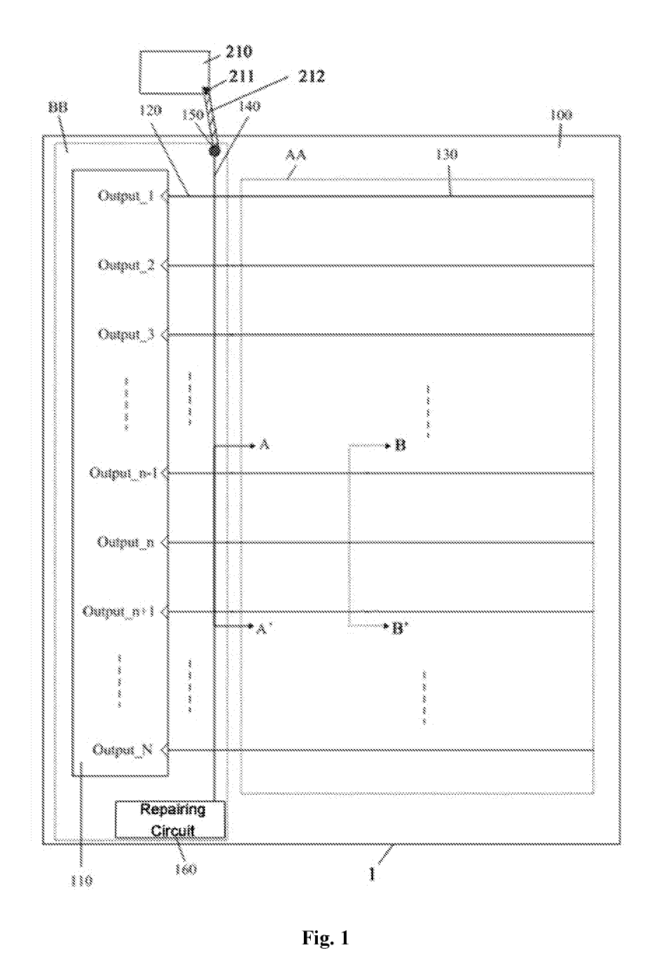

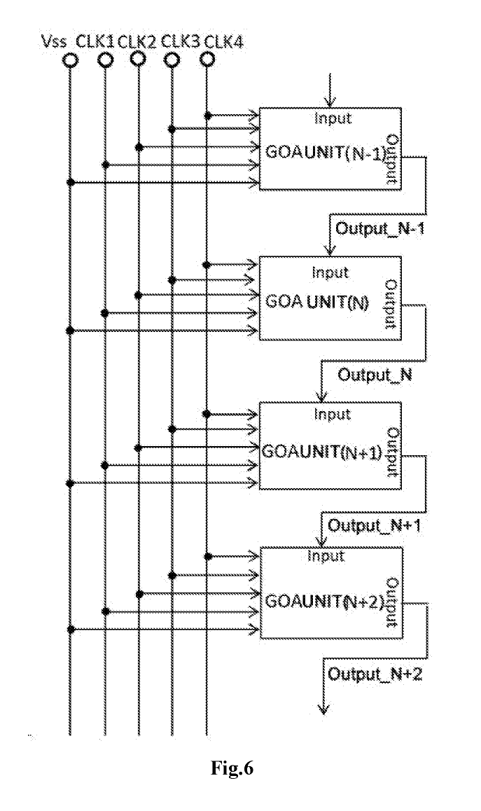

The embodiments of the present disclosure provide an array substrate 1. As shown in FIG. 1 to FIG. 3, the array substrate 1 includes a base substrate 100, a display region AA and a non-display region BB. The display region AA and the non-display region BB are arranged on the base substrate 100, and may include electrical circuits. The non-display region BB includes a gate driving circuit 110 and a plurality of driving-signal traces 120. The gate driving circuit 110 may be formed by a plurality of shift registers that are cascaded (see FIG. 6) to form a plurality of stages, and may include a plurality of driving-signal output terminals Output n (n=1, 2, 3 . . . N, where N is a positive integer). Each of the plurality of shift registers may output a driving signal though one of the plurality of driving-signal output terminals. Each of the plurality of driving-signal traces 120 is connected with one of the plurality of driving-signal output terminals. The display region AA includes a plurality of gate lines 130. Each of the plurality of gate lines 130 may be electrically connected with one of the plurality of driving-signal traces 120. The non-display region BB further includes at least one test line 140 and at least one connection terminal 150. One end of each of the at least one test line 140 may be electrically connected with one of the at least one connection terminal 150.

The at least one test line 140 and at least one of the plurality of driving-signal traces 120 overlap with each other and are insulated from each other. The at least one connection terminal 150 is used to be electrically connected with a detection device. The detection device may include at least one detection circuit, such as an external detection circuit board (not shown in FIG. 1 to FIG. 3), and at least one detection terminal connected with the at least one detection circuit.

In the above array substrate provided by the embodiments of the present disclosure, a driving signal outputted from one of the plurality of shift registers in the gate driving circuit is provided to a corresponding one of the plurality of gate lines by a corresponding one of the plurality of driving-signal traces connected to the shift register. By providing the at least one test line, arranging the at least one test line to overlap with at least one of the plurality of driving-signal traces, and electrically connecting one end of one of the at least one test line with one of the at least one connection terminal, a position where the test line and one of the plurality of driving-signal traces overlap with each other is short-circuited when a test on the driving signal on the driving-signal trace is performed, so that the driving signal on the driving-signal trace is provided to the detection device through the connection terminal, and the driving signal on the driving-signal trace which is short-circuited with the test line is detected by electrically connecting a detection probe to the connection terminal corresponding to the test line. Compared with the relevant array substrate, damages to the gate lines during the test may be prevented, thereby avoiding problems that the display panel may not be illuminated normally and the driving signal may not be detected correctly.

It should be noted that, in the above array substrate provided by the embodiments of the present disclosure, the driving signal on one driving-signal trace on the array substrate may be tested if the non-display region includes one test line; and if the non-display region includes a plurality of test lines, the driving signals on different ones of the plurality of driving-signal traces on the array substrate may be tested, respectively.

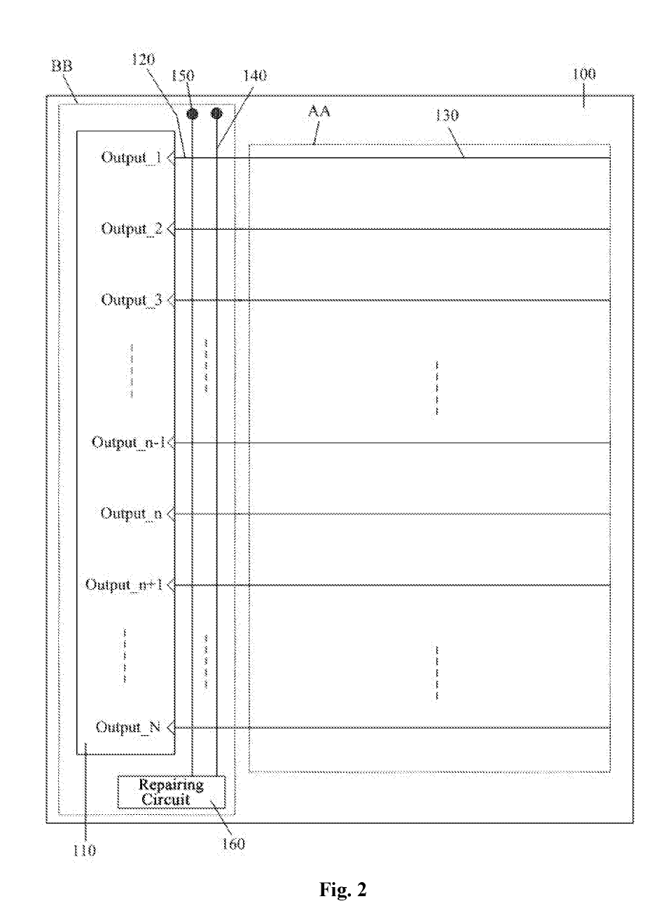

In the above array substrate provided by the embodiments of the present disclosure, the gate driving circuit 110 is located at one end of each of the plurality of gate lines 130 as shown in FIG. 1 and FIG. 2.

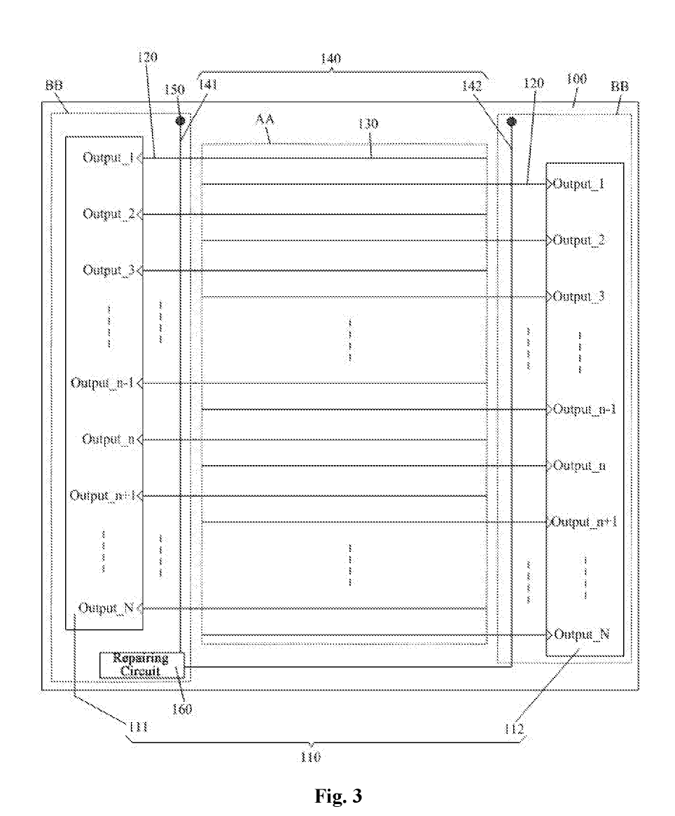

Because a phenomenon that the driving signals are delayed due to a display having a large size and long traces may occur in the display having the large size, a structure in which the gate driving circuit is disposed at both sides of the display is usually used, i.e., the gate driving circuit is disposed at both ends of the gate lines on the array substrate. In specific implementation, as shown in FIG. 3, the gate driving circuit 110 in the above array substrate provided by the embodiments of the present disclosure includes a first gate driving sub-circuit 111 and a second gate driving sub-circuit 112 disposed at both ends of each of plurality of the gate lines 130, respectively.

The test line 140 includes a first test sub-line 141 and a second test sub-line 142. An orthographic projection of the first test sub-line 141 on the base substrate 100 is located between an orthographic projection of the first gate driving sub-circuit 111 on the base substrate 100 and orthographic projections of the plurality of gate lines 130 on the base substrate 100, and an orthographic projection of the second test sub-line 142 on the base substrate 100 is located between an orthographic projection of the second gate driving sub-circuit 112 on the base substrate 100 and orthographic projections of the plurality of gate lines 130 on the base substrate 100.

Generally, when the driving signal detected on one of the plurality of driving-signal traces does not satisfy a requirement on a correct driving signal in one of the plurality of gate lines corresponding to the driving-signal trace, the correct driving signal may be inputted into the gate line by inputting the correct driving signal to the driving-signal trace, thereby making pixels on the array substrate display normally. Therefore, in specific implementation, the above array substrate provided by the embodiments of the present disclosure includes further a repairing circuit 160 electrically connected with another end of the test line 140 as shown in FIG. 1 to FIG. 3. The repairing circuit 160 may be arranged in the display region or the non-display region.

In specific implementation, if the driving signal detected on one of the plurality of driving signal traces is different from a corresponding driving signal in a corresponding one of the plurality of gate lines in the above array substrate provided by the embodiments of the present disclosure, the repairing circuit 160 is configured to provide the corresponding driving signal to the driving-signal trace through the test line after the driving signal trace and a driving-signal output terminal of one of the plurality of shift registers corresponding to the driving signal trace are disconnected electrically.

In specific implementation, in the above array substrate provided by the embodiments of the present disclosure, an angle between an extension direction of the test line and an extension direction of the driving-signal trace may be any angle other than 0° which is not specifically defined herein.

Optionally, in the above array substrate provided by the embodiments of the present disclosure, the extension direction of the test line 140 is perpendicular to the extension direction of the driving-signal trace 120 in specific implementation as shown in FIG. 1 to FIG. 3 so as to decrease a transmission delay of the driving signal due to the test line being long.

In specific implementation, the above array substrate provided by the embodiments of the present disclosure may include a source-drain electrode layer 190. The source-drain electrode layer 190 is located at one side of the base substrate 100 having the plurality of driving-signal traces 120 and is insulated from the plurality of driving-signal traces 120. The test line 140 and the source-drain electrode layer 190 are disposed at the same layer and are made of the same material. In this way, a pattern structure when forming the source-drain electrode layer needs to be changed during manufacturing the array substrate, and patterns of the source-drain electrode layer and the test line may be formed through one patterning process without an additional process for manufacturing the test line. Thus, a manufacturing process may be simplified, and a manufacturing cost may be reduced.

In specific implementation, the test line may be made of a metal material. Other conductive materials may be used for manufacturing the test line, which is not specifically defined herein.

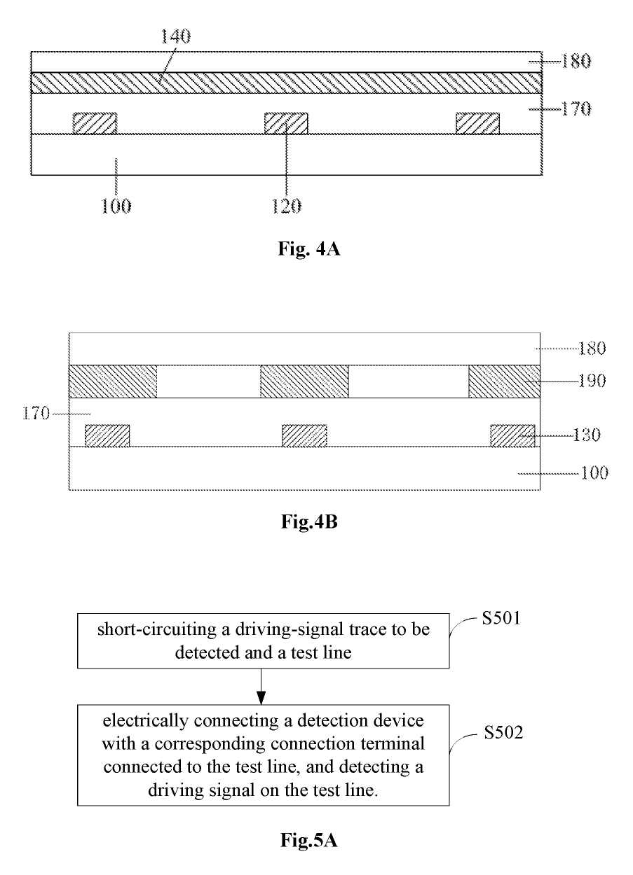

In specific implementation, the above array substrate provided by the embodiments of the present disclosure may further include a first insulation layer 170 located between a layer where the test line 140 is disposed and a layer where the plurality of driving-signal traces 120 are located, as shown in FIG. 4A.

In specific implementation, the above array substrate provided by the embodiments of the present disclosure may further include a second insulation layer 180 located at one side of the test line 140 away from the base substrate 100, as shown in FIG. 4A, i.e., located above the test line 140.

In specific implementation, in order to prevent water from affecting the test line, the second insulation layer in the above array substrate provided by the embodiments of the present disclosure may be made of a material with a waterproof function, such as a material used for forming a passivation layer in the array substrate, which is not specifically defined herein.

In specific implementation, the plurality of gate lines and the plurality of driving-signal traces in the above array substrate provided by the embodiments of the present disclosure may be located at the same layer and made of the same material. In this way, patterns of the plurality of gate lines and the plurality of driving-signal traces may be formed through one patterning process, the manufacturing process may be simplified and the manufacturing costs may be reduced.

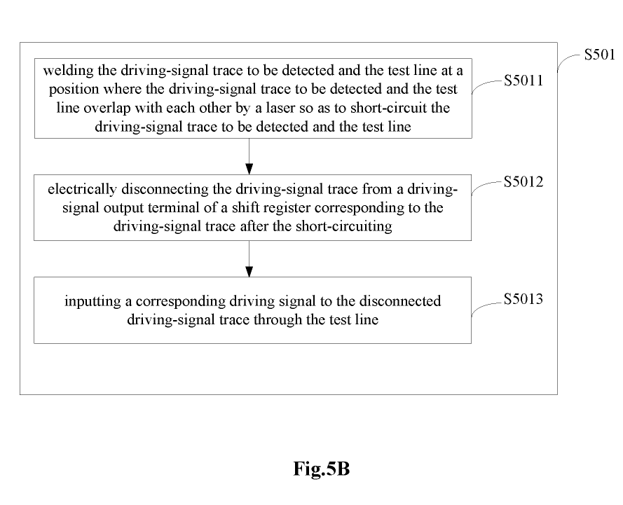

Based on the same inventive concept, the embodiments of the present disclosure further provide a method for detecting the above array substrate provided in the embodiments of the present disclosure. As shown in FIG. 5A, the method for detecting comprises step S501 to step S502.

S501: short-circuiting a driving-signal trace to be detected and a test line.

S502: electrically connecting a detection device with a corresponding connection terminal connected to the test line, and detecting a driving signal on the test line.

In specific implementation, referring to FIG. 5B, short-circuiting a driving-signal trace to be detected and a test line in the above method provided by embodiments of the present disclosure comprises step S5011.

Step S5011: welding the driving-signal trace to be detected and the test line at a position where the driving-signal trace to be detected and the test line overlap with each other by a laser so as to short-circuit the driving-signal trace to be detected and the test line.

In specific implementation, the above method provided in the embodiments of the present disclosure further comprises step S5012 to step S5013 after the welding and the short-circuiting.

Step S5012: electrically disconnecting the driving-signal trace from a driving-signal output terminal of a shift register corresponding to the driving-signal trace after the short-circuiting.

Step S5013: inputting a corresponding driving signal to the disconnected driving-signal trace through the test line.

Based on the same inventive concept, the embodiments of the present disclosure further provide a display device 10 which includes the above array substrate provided in the embodiments of the present disclosure. A principle for solving problems by the display device is similar to that by the above array substrate, implementations for the display device may refer to that for the above array substrate, and repeated parts will not be described in detail.

Further, in specific implementation, the above display device provided by the embodiments of the present disclosure further includes a detection device 210 having at least one detection terminal 211 and at least one detection circuit. Each of the at least one detection terminal 211 corresponds to one of the at least one connection terminal. In this way, when detecting the driving signal on one of the plurality of driving-signal traces, the test on the driving signal on the driving-signal trace may be performed through the following steps: short-circuiting the position where the test line and driving-signal trace overlap with each other to provide the driving signal on the driving-signal trace to the detection terminal 211 of the detection device through the test line, and electrically connecting a detection probe with the detection terminal 211 on the detection device 210. Thereby, damages to the gate lines caused during the test may be avoided.

In specific implementation, the detection device 210 may be a flexible circuit board or a printed circuit board.

In specific implementation, if the detection device 210 is a printed circuit board, the above display device provided by the embodiments of the present disclosure further includes a flexible circuit board 212 used to electrically connect the at least one connection terminal with the at least one detection terminal. The at least one connection terminal and the at least one detection terminal may be connected with each other by other electrical connections which are not specifically defined herein.

In specific implementation, the array substrate of the display device further includes a common electrode line, a common electrode feedback signal line, or other signal lines. Since an arrangement of these signal lines and their electrical connection relationship with the flexible circuit board or the printed circuit board are commonly known for one of ordinary skills in the art, no further description will be given herein.

In specific implementation, in the above display device provided by the embodiments of the present disclosure, the display device may be any product or component with a display function, such as a cell phone, a tablet, a TV set, a monitor, a notebook computer, a digital photo frame, a navigator and so on. Other components essential to a display device are provided as understood by those skilled in the art, which are not described in detail herein and should not limit the present disclosure. Implementations for the display device may refer to the embodiments of the above array substrate, and repeated parts are not described in detail.

In the embodiments of the present disclosure, the driving signal outputted from one of the plurality of the shift registers in the gate driving circuit is provided to a corresponding one of the plurality of gate lines by one of the plurality of driving-signal traces connected to the shift register; at least one test line is provided which overlaps with at least one driving-signal trace and one end of which is connected with the connection terminal; when the test on the driving signal in the driving-signal trace is performed, the position where the driving signal trace overlaps with the test line is short-circuited, so as to provide the driving signal in the driving-signal trace to the detection device through the connection terminal and test the driving signal in the driving-signal trace being short-circuited with the test line by electrically connecting the detection probe with the detection terminal corresponding to the test line.

Obviously, various variations and modifications may be made by those skilled in the art without departing from the spirit and the scope of the present disclosure. These variations and modifications are intended to be covered by the present disclosure if these variation and modification fall within the scope as defined by claims and the equivalents.

What is claimed is:

1. An array substrate, comprising:
a display region comprising a plurality of gate lines; and
a non-display region comprising at least one test line, a plurality of driving-signal traces, and a gate driving circuit comprising a plurality of driving-signal output terminals,
wherein a first end of each of the plurality of driving-signal traces is electrically connected with one of the plurality of driving-signal output terminals, a second end of the driving-signal trace is electrically connected with one of the plurality of gate lines, and the at least one test line overlaps with and is insulated from at least one of the plurality of driving-signal traces.

2. The array substrate according to claim 1, further comprising:
a repairing circuit electrically connected with a first end of the at least one test line.

3. The array substrate according to claim 1, wherein, the non-display region further comprises at least one connection terminal configured to be electrically connected with at least one detection terminal on a detection circuit, wherein the at least one connection terminal is electrically connected with a second end of the at least one test line.

4. The array substrate according to claim 1, wherein an angle other than zero degree exists between an extension direction of the at least one test line and an extension direction of each of the plurality of driving-signal traces.

5. The array substrate according to claim 1, further comprising a source-drain electrode layer,
wherein the source-drain electrode layer is located at one side of the array substrate having the plurality of driving-signal traces and is insulated from the plurality of driving-signal traces, and
the at least one test line and the source-drain electrode layer are located at a same layer and are made of a same material.

6. The array substrate according to claim 1, wherein the gate driving circuit comprises a first gate driving sub-circuit and a second gate driving sub-circuit located at both ends of each of the plurality gate lines, respectively, and
each of the at least one test line comprises a first test sub-line and a second test sub-line.

7. The array substrate according to claim 6, further comprising a base substrate, wherein, the display region and the non-display regions are arranged on the base substrate, and an orthographic projection of the first test sub-line on the base substrate is located between an orthographic projection of the first gate driving sub-circuit on the base substrate and orthographic projections of the plurality of gate lines on the base substrate, and an orthographic projection of the second test sub-line on the base substrate is located between an orthographic projection of the second gate driving sub-circuit on the base substrate and orthographic projections of the plurality of gate lines on the base substrate.

8. The array substrate according to claim 1, further comprising:
a first insulation layer located between a layer at which the at least one test line is located and a layer at which the plurality of driving-signal traces are located.

9. The array substrate according to claim 1, further comprising:
a second insulation layer located above the at least one test line and made of a material with a waterproof function.

10. The array substrate according to claim 9, wherein the gate driving circuit comprises a plurality of shift registers cascaded to form a plurality of stages, each of the plurality of shift registers is configured to output a driving signal through a corresponding one of the plurality of driving-signal output terminals of the gate driving circuit.

11. A display device, comprising:
the array substrate according to claim 1.

12. The display device according to claim 1, further comprising:
a detection device comprising at least one detection terminal, wherein the non-display region further comprises at least one connection terminal electrically connected with a second end of the at least one test line and each of the at least one connection terminal is configured to be electrically connected with one of the at least one detection terminal on the detection device.

13. The display device according to claim 12, wherein the detection circuit is a flexible circuit board or a printed circuit board.

14. The display device according to claim 13, wherein in case that the detection device is the printed circuit board, the display device further comprises a flexible circuit board configured to electrically connect the at least one connection terminal with the at least one detection terminal.

15. A method for detecting the array substrate according to claim 1, the method comprising:
short-circuiting at least one of the plurality of driving-signal traces to be detected and the at least one test line; and
electrically connecting a detection device with at least one connection terminal electrically connected to the at least one test line, and detecting a driving signal on the at least one test line.

16. The method according to claim 15, wherein after short-circuiting at least one of the plurality of driving-signal traces to be detected and the at least one test line, the method further comprises:
electrically disconnecting the short-circuited at least one of the plurality of driving-signal traces from at least one of the plurality of driving-signal output terminals in the gate driving circuit; and
inputting a corresponding driving signal to the disconnected at least one of the plurality of driving-signal traces through the at least one test line.

17. The method according to claim 15, wherein the short-circuiting at least one of the plurality of driving-signal traces to be detected and the at least one test line comprises:
welding the at least one of the plurality of driving-signal traces to be detected and the at least one test line at a position where the at least one of the plurality of driving-signal traces to be detected and the at least one test line overlap with each other by a laser so as to short-circuit the at least one of the plurality of the driving-signal traces to be detected and the at least one test line.

18. The method according to claim 16, wherein electrically disconnecting the short-circuited at least one of the plurality of driving-signal traces from at least one of the plurality of driving-signal output terminals in the gate driving circuit, comprises:
electrically disconnecting the short-circuited at least one of the plurality of driving-signal traces from at least one of the plurality of driving-signal output terminals of a plurality of shift registers cascaded to form a plurality of stages in the gate driving circuit, and each of the plurality of driving-signal output terminals corresponds to one of the plurality of shift registers.
